(19) United States
(12) Patent Application Publication
(10) Pub. No.: US 2012/0314392 A1
(43) Pub. Date: Dec. 13, 2012

(54) CAPACITOR ARRAY SUBSTRATE

(75) Inventors: Wing-Kai Tang, Hsinchu City (TW); Ching-Chun Lin, New Taipei City (TW); Hao-Jan Huang, Hsinchu City (TW); Yu-Tsung Lu, Hsinchu City (TW); Jiun-Jie Tsai, Hsinchu City (TW); Tsen-Wei Chang, Taichung City (TW)

(73) Assignee: NOVATEK MICROELECTRONICS CORP., Hsinchu (TW)

(21) Appl. No.: 13/459,259

(22) Filed: Apr. 30, 2012

(30) Foreign Application Priority Data
Jun. 7, 2011 (TW) 100119880

(51) Int. Cl. H05K 7/00

(52) U.S. Cl. 361/782

(57) ABSTRACT

A capacitor array substrate includes a substrate, first traces, second traces, capacitors, connecting lines, and signal lines. The substrate has a first, a second, and a third side. The first side is connected with the second and the third side. The first traces are disposed on the substrate in parallel and are not vertical or parallel to the first side. The second traces are disposed on the substrate in parallel. The capacitors are disposed on the substrate at intersections of the first and the second traces and are connected to the first and the second traces. The connecting lines are disposed on the second and the third side of the substrate. Each connecting line is connected to a first and a second trace. The signal lines are disposed on the substrate. Each signal line is connected to a first or a second trace and transmits signals from the first side.

### CROSS-REFERENCE TO RELATED APPLICATION

This application claims the priority benefit of Taiwan application serial no. 100119880, filed on Jun. 7, 2011. The entirety of the above-mentioned patent application is hereby incorporated by reference herein and made a part of this specification.

### BACKGROUND OF THE INVENTION

1. Field of the Invention

The invention generally relates to a substrate, and more particularly, to a capacitor array substrate.

2. Description of Related Art

FIG. 1 is a diagram of a conventional capacitor array substrate. Referring to FIG. 1, in the conventional capacitor array substrate 100, the capacitors 110 arranged in an array are connected to the horizontal traces 120 and the vertical traces 130. Because the traces 120 and the traces 130 are respectively parallel to two sides of the capacitor array substrate 100, to carry out all signal transmissions at the same side, signal lines 140 for the traces 120 need to be laid out at one side of the capacitor array substrate 100. As a result, the width of the side of the capacitor array substrate 100 is greatly increased. Thus, not only the cost of the capacitor array substrate 100 is increased, but the long signal lines 140 may cause the signal quality to decrease.

### SUMMARY OF THE INVENTION

Accordingly, the invention is directed to a capacitor array substrate of reduced size.

The invention provides a capacitor array substrate including a substrate, a plurality of first traces, a plurality of second traces, a plurality of capacitors, a plurality of connecting lines, and a plurality of signal lines. The substrate has a first side, a second side, and a third side. The first side is connected with the second side. The first side is connected with the third side. The first traces are disposed on the substrate in parallel with each other. Each of the first traces is not vertical or parallel to the first side. The second traces are disposed on the substrate in parallel with each other. The capacitors are disposed on the substrate at intersections of the first traces and the second traces and are connected to the first traces and the second traces. The connecting lines are disposed on the second side and the third side of the substrate. Each of the connecting lines is connected to one of the first traces and one of the second traces. The signal lines are disposed on the substrate. Each of the signal lines is connected to one of the first traces or one of the second traces and transmits signals from the first side.

According to an embodiment of the invention, the first traces are vertical to the second traces.

According to an embodiment of the invention, the angles formed by the first traces and the first side are 45°.

According to an embodiment of the invention, the connecting lines do not intersect each other.

According to an embodiment of the invention, the connecting lines intersect each other.

According to an embodiment of the invention, the first side is vertical to the second side.

As described above, in a capacitor array substrate provided by the invention, all the traces connecting the capacitors are slanted with respect to the sides of the substrate and then connected with the connecting lines, so that the layout area can be reduced.

These and other exemplary embodiments, features, aspects, and advantages of the invention will be described and become more apparent from the detailed description of exemplary embodiments when read in conjunction with accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram of a conventional capacitor array substrate.

FIG. 2 is a diagram of a capacitor array substrate according to an embodiment of the invention.

FIG. 3 is a diagram of a capacitor array substrate according to another embodiment of the invention.

FIG. 4 is a diagram of a capacitor array substrate according to another embodiment of the invention.

FIG. 5 is a diagram of a capacitor array substrate according to another embodiment of the invention.

FIG. 6 is a diagram of a capacitor array substrate according to another embodiment of the invention.

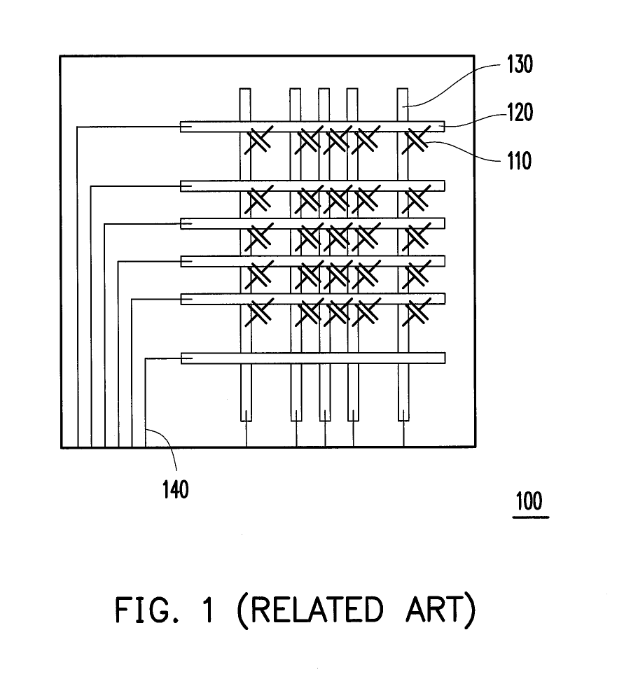

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

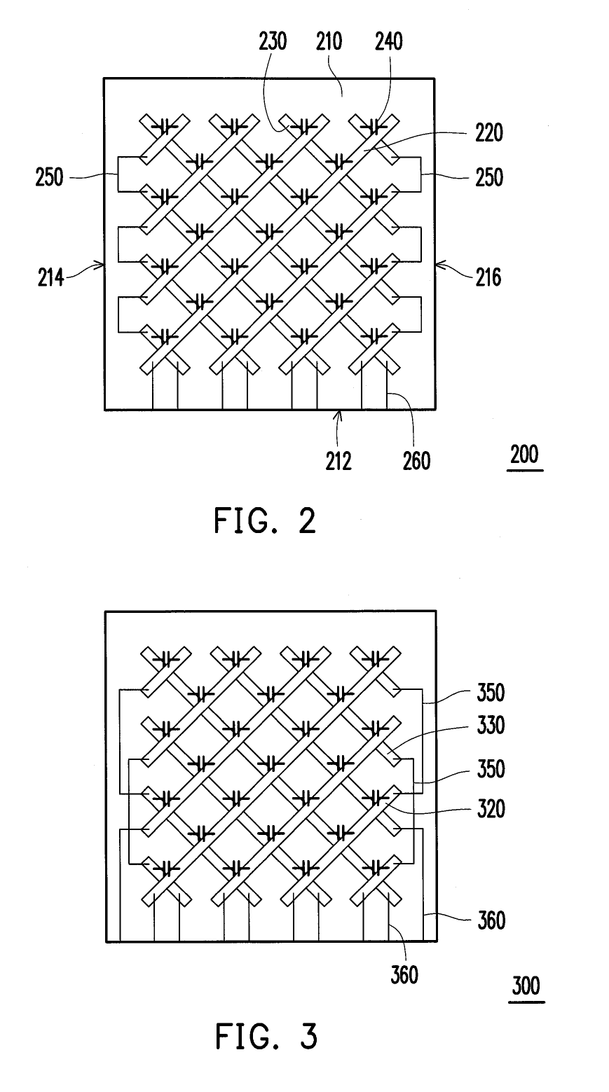

FIG. 2 is a diagram of a capacitor array substrate according to an embodiment of the invention. Referring to FIG. 2, in the present embodiment, the capacitor array substrate 200 includes a substrate 210, a plurality of first traces 220, a plurality of second traces 230, a plurality of capacitors 240, a plurality of connecting lines 250, and a plurality of signal lines 260. The substrate 210 has a first side 212, a second side 214, and a third side 216. The first side 212 is connected with the second side 214, and the first side 212 may be vertical to the second side 214. The first side 212 is connected with the third side 216, but the first side 212 may be vertical or not vertical to the third side 216. The substrate 210 usually presents a rectangular shape. However, the shape of the substrate 210 is not limited in the invention. The first traces 220 are disposed on the substrate 210 in parallel with each other, and each first trace 220 is not vertical or parallel to the first side 212. In other words, if the edge of the first side 212 is horizontal, the first traces 220 are not vertical or horizontal. The second traces 230 are disposed on the substrate 210 in parallel with each other.

Herein the terms “vertical” and “parallel” only refer to approximate instead of precise states, and near vertical and near horizontal states caused by process errors or purposeful modifications are acceptable.

The capacitors 240 are disposed on the substrate 210. Each capacitor 240 is located at the intersection of a first trace 220 and a second trace 230 and is connected to a first trace 220 and a second trace 230. The connecting lines 250 are disposed on the second side 214 and the third side 216 of the substrate 210. Each connecting line 250 is connected to a first trace 220 and a second trace 230. The signal lines 260 are disposed on the substrate 210. Each signal line 260 is connected to a first trace 220 or a second trace 230 and transmits signals from the first side 212.

Based on the disposition described above, each capacitor 240 is controlled through two signal lines 260, and the capacitance variation on each capacitor 240 can be detected through two signal lines 260. Besides, only small amounts of space are reserved on the second side 214 and the third side 216 of the substrate 210 for disposing the connecting lines 250. Thus, in the present embodiment, the purpose of transmitting signals from a single side can be accomplished in the capacitor array substrate 200 of reduced size, so that the cost of the capacitor array substrate 200 is greatly reduced. Additionally, the signal lines 260 and the connecting lines 250 can be managed to have shorter lengths so that the signal transmission quality can be improved.

In the present embodiment, the first traces 220 are vertical to the second traces 230. Additionally, in the present embodiment, the angles formed by the first traces 220 and the first side 212 are 45°. Moreover, in the present embodiment, the connecting lines 250 do not intersect each other (i.e., each connecting line 250 is connected to the closest first trace 220 and second trace 230).

FIG. 3 is a diagram of a capacitor array substrate according to another embodiment of the invention. Referring to FIG. 3, the capacitor array substrate 300 in the present embodiment is similar to the capacitor array substrate 200 illustrated in FIG. 2, and the difference between the two is that in the present embodiment, the connecting lines 350 intersect each other or may even intersect the signal lines 360. In other words, each connecting line 350 is not connected to the closest first trace 320 or second trace 330. Such a design optimizes the potential distribution of the capacitor array and accordingly improves the performance of the capacitor array substrate 300.

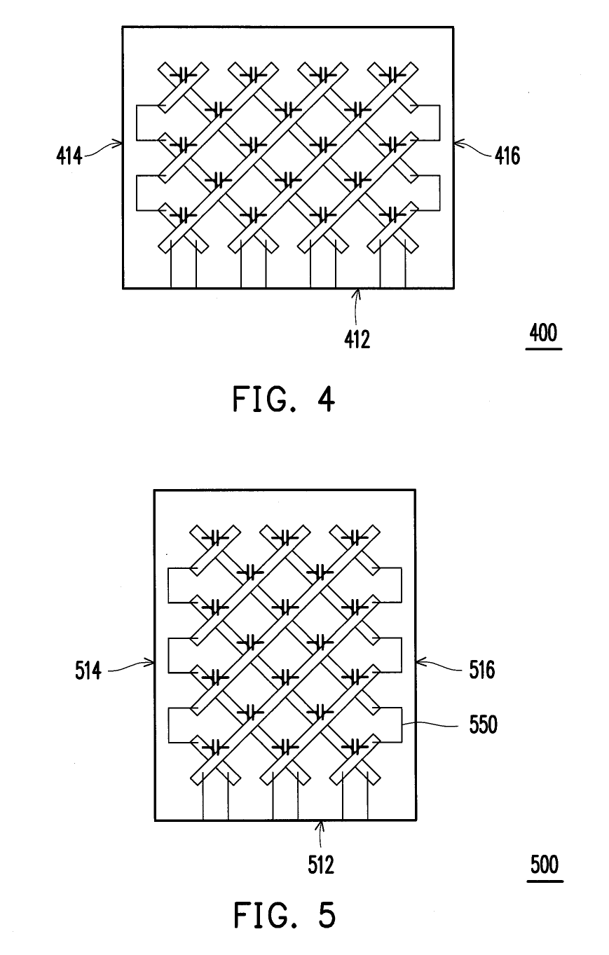

FIG. 4 is a diagram of a capacitor array substrate according to another embodiment of the invention. Referring to FIG. 4, the capacitor array substrate 400 in the present embodiment is similar to the capacitor array substrate 200 illustrated in FIG. 2, and the difference between the two is that in the capacitor array substrate 400 of the present embodiment, the first side 412 is longer than the second side 414 and the third side 416. It can be understood according to the present embodiment that the invention can be applied to the capacitor array substrate 400 which presents a rectangular shape.

FIG. 5 is a diagram of a capacitor array substrate according to another embodiment of the invention. Referring to FIG. 5, the capacitor array substrate 500 in the present embodiment is similar to the capacitor array substrate 200 illustrated in FIG. 2, and the difference between the two is that in the capacitor array substrate 500 of the present embodiment, the first side 512 is shorter than the second side 514 and the third side 516. It can be understood according to the present embodiment that the invention can be applied to the capacitor array substrate 500 which presents a rectangular shape and has its shorter side as the signal transmission side. Additionally, on the second side 514 or the third side 516 of the capacitor array substrate 500, some of the connecting lines 550 close to the first side 512 can be replaced by signal lines directly connected to the signal transmission side.

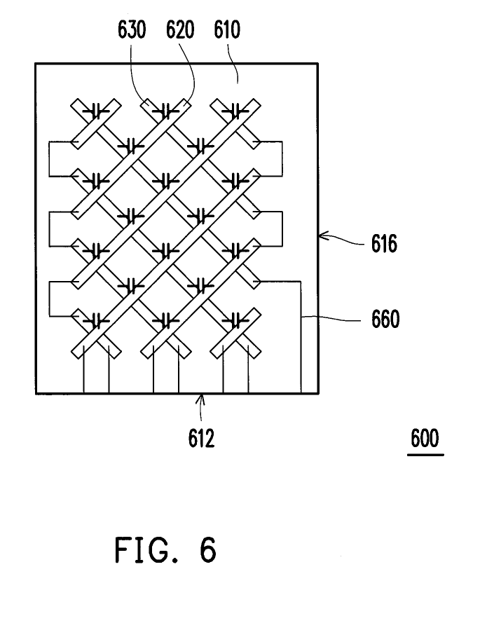

FIG. 6 is a diagram of a capacitor array substrate according to another embodiment of the invention. Referring to FIG. 6, the capacitor array substrate 600 in the present embodiment is similar to the capacitor array substrate 500 illustrated in FIG. 5, and the difference between the two is that in the present embodiment, the signal lines 660 are connected not only to the first traces 620 and the second traces 630 closest to the first side 612. Instead, some of the signal lines 660 on the third side 616 are extended toward inside of the substrate 610 and connected to the first traces 620 or the second traces 630 located inside the substrate 610.

In summary, in a capacitor array substrate provided by the invention, all the traces connecting the capacitors are slanted with respect to the sides of the substrate so that signals can be transmitted from the same side. Additionally, connecting lines are disposed to reduce the layout area without sacrificing the working area, so that the cost of the capacitor array substrate can be reduced.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A capacitor array substrate, comprising:
a substrate, having a first side, a second side, and a third side, wherein the first side is connected with the second side, and the first side is connected with the third side;
a plurality of first traces, disposed on the substrate in parallel with each other, wherein each of the first traces is not vertical or parallel to the first side;
a plurality of second traces, disposed on the substrate in parallel with each other;
a plurality of capacitors, disposed on the substrate at intersections of the first traces and the second traces, and connected to the first traces and the second traces;
a plurality of connecting lines, disposed on the second side and the third side of the substrate, respectively connected to one of the first traces and one of the second traces; and
a plurality of signal lines, disposed on the substrate, respectively connected to one of the first traces or one of the second traces, and transmitting signals from the first side.

2. The capacitor array substrate according to claim 1, wherein the first traces are vertical to the second traces.

3. The capacitor array substrate according to claim 1, wherein angles between the first traces and the first side are 45°.

4. The capacitor array substrate according to claim 1, wherein the connecting lines do not intersect each other.

5. The capacitor array substrate according to claim 1, wherein the connecting lines intersect each other.

6. The capacitor array substrate according to claim 1, wherein the first side is vertical to the second side.
